(19) United States
(12) Patent Application Publication
(10) Pub. No.: US 2002/0168802 A1
(43) Pub. Date: Nov. 14, 2002

(54) SiGe/SOI CMOS and method of making the same

(76) Inventors: Sheng Teng Hsu, Camas, WA (US); Douglas J. Tweet, Camas, WA (US); David R. Evans, Beaverton, OR (US)

Correspondence Address: David C. Ripma, Patent Attorney, Sharp Laboratories of America, Inc., 5750 NW Pacific Rim Boulevard, Camas, WA, 98607, US

(21) Appl. No.: 10/016,373

(22) Filed: Oct. 30, 2001

Related U.S. Application Data
(63) Continuation-in-part of application No. 09/855,392, filed on May 14, 2001.

(51) Int. Cl. H01L 21/44

(52) U.S. Cl. 438/149; 438/118; 438/166; 438/106

(57) ABSTRACT

The present invention provides a method of fabricating a simple SiGe/SOI structure. In particular, the top silicon layer of a SOI is converted to Si₁₋ₓGeₓ, by growing a SiGe epitaxial layer followed by relaxation annealing at a temperature between 550° C. to 1050° C. This temperature treatment relaxes the SiGe to convert the top silicon layer into a relaxed SiGe layer and eliminates defects in the SOI film. Accordingly, a very low defect density SiGe crystal is obtainable. The SiGe layer is capped with an epitaxial silicon layer. Because the silicon layer is grown onto the relaxed SiGe, the top silicon layer is a strained silicon layer. Therefore, higher electron and hole mobility are obtained. The buried oxide interface acts as a buffer for the SiGe relaxation. There is no requirement for a graded SiGe layer. As a result the defect density in this structure can be substantially lower than that of prior art structures.

This application is a Continuation-In-Part of U.S. patent application Ser. No. 09/855,392, filed on May 14, 2001, and entitled Enhanced Mobility NMOS and PMOS Transistors Using Strained Si/SiGe Layers on Silicon-On-Insulator Substrates.

### FIELD OF THE INVENTION

This invention relates to high speed CMOS integrated circuits and, more particularly, to high speed CMOS integrated circuits including a relaxed Silicon Germanium (SiGe) layer on top of a silicon-on-insulator (SOI) buried oxide (BOX) wherein the structure has a low defect density.

### BACKGROUND OF THE INVENTION

Silicon Germanium (SiGe) metal oxide semiconductor (MOS) transistors have been fabricated on surface strained silicon as well as on buried strained silicon structures. The device typically consists of a thick layer of graded Si₁₋ₓGeₓ, where x varies from 0.0 at the bottom to about 0.3 at the top of the 1 μm to 2 μm relaxed SiGe layer. A layer of 50 nm to 150 nm of relaxed Si₁₋ₓGeₓ is grown on top of the graded SiGe followed by a strained silicon epitaxial layer for the surface strained MOS transistor. For buried strained MOS transistors, an additional layer of SiGe is deposited onto the strained silicon layer. This structure is able to enhance the field effective mobility by 80% from that of a pure silicon device. For pMOST devices, an effective hole mobility of 400 cm²/Vs has been obtained. In particular, Applicants obtained higher than 50% enhancement of effective hole mobility on a simple silicon cap on strained SiGe hole confinement pMOSTs.

SiGe/SOI transistors fabricated on a similar structure but with silicon oxide buried in the relaxed graded SiGe layer have also been fabricated. The gain of hole mobility and electron mobility of this SiGe/SOI structure is higher than those of silicon control transistors by 45% and 60%, respectively. This structure is very complex and the crystalline defect density is too high for large-scale integrated circuit application.

U.S. Pat. Ser. No. 5,726,459, entitled “Ge-Si SOI MOS Transistor and Method for Fabricating Same,” by S. T. Hsu and T. Nakado, issued on Mar. 10, 1998, discloses a device wherein ion implantation is used to form the Ge doped silicon layer. The Ge ion dose is very high and the implantation time is long. Additionally, the silicon layer may be completely amorphorized during the Ge ion implantation and may be unable to re-crystallize. Accordingly, good quality SiGe films cannot reliably be obtained using the method disclosed therein.

Accordingly, there is a need for a simple SiGe/SOI structure. Additionally, there is a need for a method of fabricating such a simple SiGe/SOI CMOS structure.

### SUMMARY OF THE INVENTION

The present invention provides a simple SiGe/SOI structure and a method of fabricating the same. In particular, the top silicon layer of a SOI is converted to Si₁₋ₓGeₓ, by growing a SiGe epitaxial layer followed by diffusion annealing at a temperature in a range of 550° C. to 1050° C. A second anneal step, referred to as a relaxation anneal step, typically is conducted at a temperature in a range of 1050° C. to 1200° C. This temperature treatment diffuses the Ge to convert the top silicon layer into a relaxed SiGe layer and eliminates any defects in the SOI film. Accordingly, a defect free SiGe crystal is obtainable. The SiGe layer is capped with an epitaxial silicon layer. Because the silicon layer is grown onto the relaxed SiGe, the top silicon layer is a strained silicon layer. Therefore, higher electron and hole mobilities are obtained. The buried oxide interface acts as a buffer for the SiGe relaxation. There is no requirement for a graded SiGe layer. As a result, the defect density in this structure can be substantially lower than that of the structures of the prior art.

The fabrication process is as follows. First, the top silicon layer of the SOI substrate is thinned to 10 nm to 30nm. Second, an epitaxial layer of Si₁₋ₓGeₓ is grown, where 0.2<×<0.5. The film thickness typically is 20 nm to 40 nm. Third, ion implantation of boron and phosphorus to the p-well and n-well, respectively, is conducted for nMOST and pMOST threshold voltage control. Fourth, the structure is diffusion annealed at a temperature in a range of 550° C. to 1050° C. for 0.5 to 4 hours. This heat treatment diffuses the Ge to convert the top silicon film into relaxed Si₁₋ₓGeₓ where x may not be constant through the film. This heat treatment also eliminates some or all of the defects in the SOI film. A second relaxation anneal step may be conducted at a temperature in a range of 1050° C. to 1200° C. for a very short time, such as only a few seconds. A low defect density in the relaxed SiGe on SOI wafer is obtained. Fifth, a cap silicon layer is grown. Because the underlying SiGe is relaxed, the cap silicon layer is laterally tensily strained. Sixth, a gate oxide is grown and a first polysilicon layer, poly1, is deposited. Seventh, photoresist is applied to protect the active areas. The poly1, oxide, and SiGe are then etched, and the resist is stripped. Eighth, a low temperature thermal oxide of 10 nm to 20 nm is grown. A layer of 500 nm to 2000 nm CVD oxide is then deposited. Ninth, a plasma etch of the oxide is conducted to remove all the oxide from the surface of the poly1. This forms a sidewall oxide on the active area. Tenth, 50 nm to 200 nm of polysilicon, poly2, is deposited. The poly1 and poly2 combine to form the gate electrode. Eleventh, application of a photoresist and etching of the polysilicon gate electrode are then conducted, and the resist is stripped. An additional photoresist is used for the source/drain implant. Twelfth, a passivation oxide and the metallization layers are deposited. The final device is thus obtained.

During these steps, a low thermal budget is necessary to avoid out diffusion of the Ge into the strained Si layer. In addition, it is well known that the reliability of a thin oxide grown on SiGe is not as good as the reliability of an oxide grown on silicon. This process provides a low thermal budget. Moreover, there is no thin gate oxide grown on a SiGe layer, thereby avoiding the disadvantages of the prior art processes and devices.

Accordingly, an object of the invention is to provide a simple SiGe/SOI structure and a method of producing the same.

Another object of the invention is to provide a high speed CMOS integrated circuit, and a method of manufacturing the same, wherein the circuit includes a relaxed Silicon Germanium (SiGe) layer on top of a silicon-on-insulator (SOI) buried oxide (BOX) wherein the structure has a low defect density.

### BRIEF DESCRIPTION OF THE DRAWINGS

FIG. 1 is a cross sectional side view of the device during fabrication showing the oxide, silicon and SiGe layers.

FIG. 2 is a cross sectional side view of the device during fabrication showing the oxide, pSiGe/nSiGe, oxide and polysilicon layers.

FIG. 3 is a cross sectional side view of the device during fabrication showing the pMOS and nMOS areas.

FIG. 4 is a cross sectional side view of the device during fabrication showing the oxide layer deposited on the pMOS and nMOS areas.

FIG. 5 is a cross sectional side view of the device during fabrication showing the etched oxide layer on the pMOS and nMOS areas.

FIG. 6 is a cross sectional side view of the device during fabrication showing the gate regions.

FIG. 7 is a cross sectional side view of the device during fabrication showing the fully fabricated device.

FIG. 8 is a flowchart showing the fabrication process of the present invention.

### DETAILED DESCRIPTION OF THE PREFERRED EMBODIMENTS

FIG. 1 is a cross sectional side view of the device during fabrication showing the oxide, silicon and SiGe layers. In particular, the method of the present invention comprises a method wherein the top silicon layer of a SOI film is converted to Si₁₋ₓGeₓ by growing a SiGe epitaxial layer followed by diffusion annealing at a temperature between 550° C. to 1050° C. for a time period in a range of ten to forty minutes. A second relaxation annealing step may be conducted at a temperature between 1050° C. to 1200° C. for a short time period, such as for several seconds. The first anneal step diffuses the Ge to define a somewhat uniform SiGe layer that is at least partially relaxed. The second anneal step results in a relaxed SiGe layer. This temperature treatment diffuses the Ge to convert the top silicon layer into a relaxed SiGe layer and minimizes any defects in the SOI film. Accordingly, a low defect SiGe crystal is obtainable. The SiGe is capped with an epitaxial silicon layer. Because the silicon layer is grown onto the relaxed SiGe layer, the top silicon layer is a strained silicon layer. Therefore, higher electron and hole mobilities are obtained. The buried oxide interface acts as a buffer for the SiGe relaxation. There is no requirement for a graded SiGe layer. As a result, the defect density in this structure can be substantially lower than that of structures known in the prior art.

The first step of the fabrication process includes providing a substrate 10 having an oxide layer 12 and a top silicon layer 14. Top silicon layer 14 is thinned to a thickness 16 of approximately 10 nm to 30 nm. An epitaxial layer 18 of Si₁₋ₓGeₓ is grown on top silicon layer 14, where x is in a range of 0.1 to 0.9, and preferably in a range of 0.2 to 0.5. The film thickness 20 of layer 18 is typically approximately 20 nm to 40 nm.

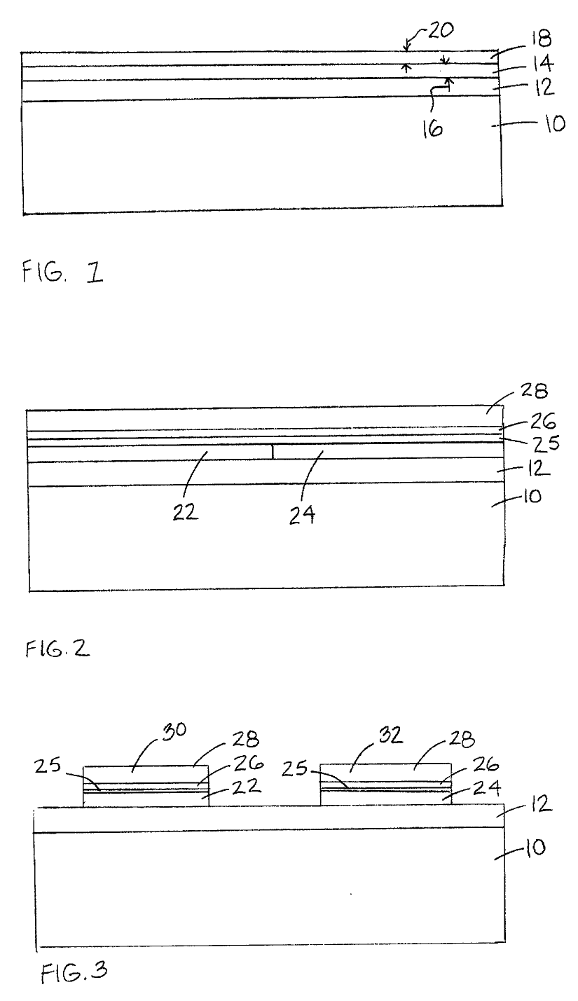

FIG. 2 is a cross sectional side view of the device during fabrication showing oxide, pSiGe/nSiGe, silicon, oxide and polysilicon layers. Fabrication of the device is as follows. Boron and phosphorus ions are implanted to form a p-well 22 and a n-well 24, respectively, for nMOST and pMOST threshold voltage control. The structure is then diffusion annealed at a temperature in a range of 550° C. to 1050° C. for approximately 0.5 to 4 hours. This heat treatment diffuses the Ge to convert the top silicon film 22 and 24 into an at least partically relaxed Si₁₋ₓGeₓ film where x may not be constant through the film. Typically, a second relaxation anneal step is then conducted at a temperature in a range of 1050° C. to 1200° C. for approximately one to ten seconds. As a result of this step, a Si_{1-y}Ge_{y} layer is formed from the Si and the Si₁₋ₓGeₓ layers, wherein y is less than x. The Si_{1-y}Ge_{y} layer typically is relaxed. This second heat treatment also eliminates some or all defects in the SOI film. Moreover, the second, spike anneal relaxes the Si_{1-y}Ge_{y} layer. Accordingly, a low defect density relaxed SiGe layer on the SOI wafer is obtained. A thin layer 25 of silicon, having a thickness in a range of approximately 5 nm to 20 nm, is epitaxially grown onto the SiGe layer. A gate oxide layer 26 is then grown and a cap polysilicon layer 28, poly, is deposited on SiGe layers 22 and 24. The thickness of layer 28 typically is in a range of 100 nm to 200 nm. Thin silicon layer 25 may be deposited before or after the second, relaxation anneal step, also called a spike anneal step. In either method, the grown silicon layer 25 typically will be a strained silicon layer.

FIG. 3 is a cross sectional side view of the device during fabrication showing the pMOS and nMOS areas. In particular, photoresist is applied to portions of active areas 22 and 24 to protect them during the etching of poly1 layer 28, oxide layer 26, silicon layer 25, and the outer regions of pSiGe region 22 and nSiGe region 24. The photoresist is then stripped to yield active nMOS 30 and pMOS 32 regions.

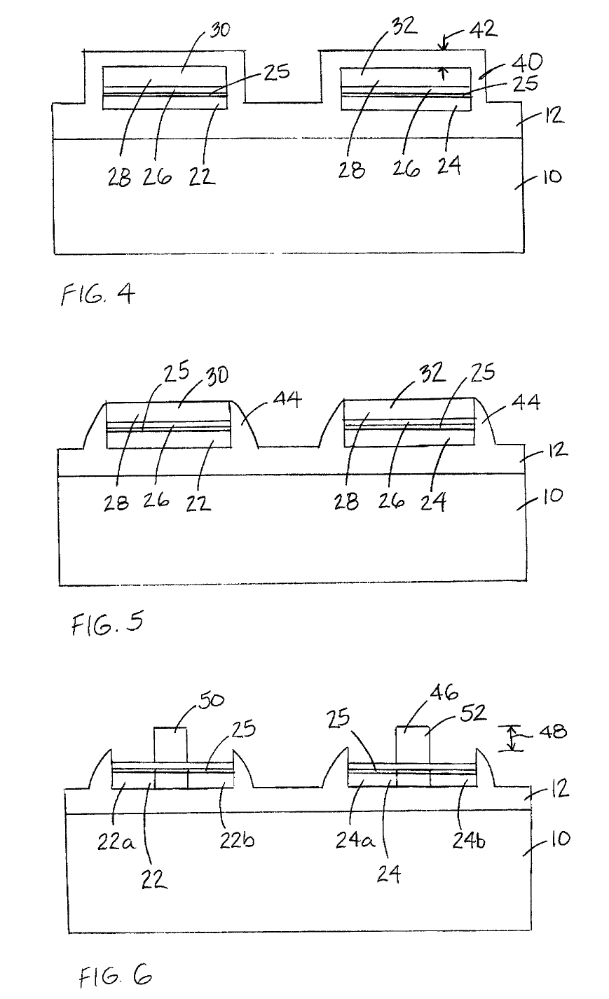

FIG. 4 is a cross sectional side view of the device during fabrication showing an oxide layer deposited on the pMOS and nMOS areas. In particular, a low temperature thermal oxide layer is grown over the device of FIG. 3, wherein the low thermal budget oxide layer typically has a thickness of approximately 5 nm to 10 nm. Oxide layer 40 is deposited by chemical vapor deposition (CVD), having a thickness 42 of approximately 50 nm to 200 nm.

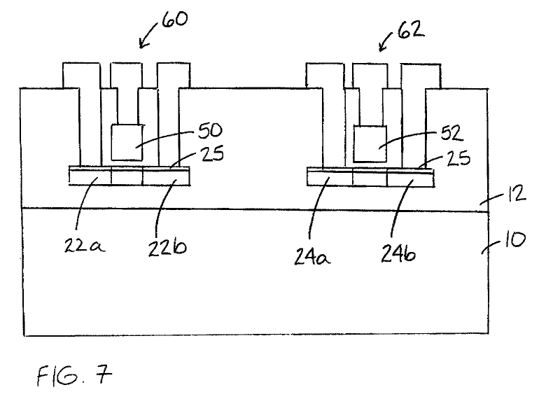

FIG. 5 is a cross sectional side view of the device during fabrication showing the oxide layer etched in the pMOS and nMOS areas. In particular, a plasma etch is conducted of the oxide layer 40 to remove all the oxide from the upper surface of poly1 layer 28. This forms a sidewall oxide 44 on the active areas 30 and 32.

FIG. 6 is a cross sectional side view of the device during fabrication showing the gate regions. In particular, a layer of polysilicon 46, poly2, is deposited on the device of FIG. 5. Poly2 layer 46 typically has a thickness 48 of approximately 100 nm to 200 nm. The poly2 and poly1 layers combine to form the gate electrodes. Photoresist is then applied and the device is etched to provide polysilicon gate electrodes 50 and 52. The photoresist is then stripped. Additional photoresist may be used for implantation of the source and drain regions in layers 22 and 24. In one embodiment, the source and drain regions 22a and 22b, respectively, of layer 22 may be doped so as to be N+ whereas the source and drain regions 24a and 24b, respectively, of layer 24 may be doped so as to be P+. Similarly, gate electrode 50 may be N+ and gate electrode 52 may be P+.

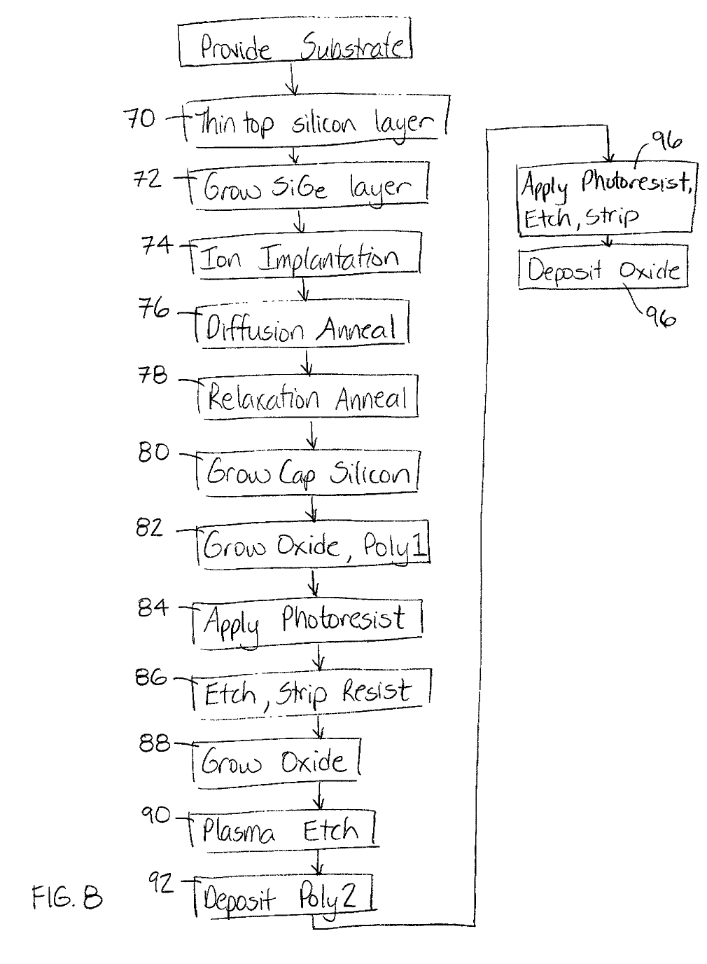

FIG. 7 is a cross sectional side view of the device during fabrication showing the filly fabricated device. In particular, this process step involves depositing a passivation oxide and then metallization of the device. This results in a nMOS structure 60 and a pMOS structure 62.

The low thermal budget provided by the steps of the present invention is necessary to avoid out diffusion of Ge into the strained Si layer. In addition, it is well known that the reliability of a thin oxide grown on a SiGe layer is not as good as that grown on a silicon layer. The process disclosed herein has a low thermal budget and does not require a thin gate oxide to be grown on the SiGe. Accordingly, there is provided a simple SiGe/SOI structure and a method of producing the same. In particular, the present invention provides a high speed CMOS integrated circuit, and a method of manufacturing the same, wherein the circuit includes a relaxed Silicon Germanium (SiGe) layer on top of a silicon-on-insulator (SOI) buried oxide (BOX), and wherein the structure has a low defect density.

As discussed above, a second, relaxation annealing step may be conducted to provide a relaxed SiGe layer on top of the SOI buried oxide (BOX). In this method, the goal is still to convert the top silicon layer of a SOI wafer to a relaxed Si_{1-y}Ge_{y}, where y is at least 0.15. This process begins by growing a blanket Si₁₋ₓGeₓ epitaxial layer where x is greater than y. The film may then be patterned with photoresist and the top SiGe/Si films may be selectively etched down to the BOX. This leaves the isolated SiGe/Si mesas, from which it is possible to anneal out the defects. Alternatively, the wafer may be left unpatterned. This step is then followed by diffusion annealing at a temperature in a range of 550° C. to 1050° C. for a time period in a range of approximately 0.5 to 4 hours. This temperature treatment diffuses the Ge to convert the top silicon layer into a relaxed Si_{1-y}Ge_{y} layer. A second annealing step may then be conducted. In particular, a spike annealing step at a temperature in a range of 1050° C. to 1200° C. may then be conducted to complete the diffusion and eliminate or reduce any defects in the SOI film. This spike or relaxation annealing step typically is conducted for a short time period, such as ten seconds or less. A low defect density Si_{1-y}Ge_{y} crystal is thus obtainable. The Si_{1-y}Ge_{y} is then capped with an epitaxial silicon layer. If the wafer has been previously patterned, the epitaxial Si cap may need to be deposited selectively. Because the silicon layer is grown onto the relaxed SiGe, the top silicon layer is a strained silicon layer. Therefore, high electron and hole mobilities are obtained. The buried oxide interface acts as a buffer for the SiGe relaxation. There is no requirement of a graded SiGe layer. As a result, the defect density in this structure can be substantially lower than that of the structures known in the prior art.

FIG. 8 is a flowchart showing the fabrication process of the present invention. First a substrate is provided. Step 70 comprises thinning the top silicon layer of the SOI substrate to a thickness of approximately 10 nm to 30 nm. Step 72 comprises growing an epitaxial layer of Si₁₋ₓGeₓ where 0.2<×<0.5. The film thickness typically is 20 nm to 40 nm. Step 74 comprises conducting ion implantation of boron and phosphorus to the p-well and n-well, respectively, for nMOST and pMOST threshold voltage control. Step 76 comprises diffusion annealing the structure at a temperature in a range of 550° C. to 1050° C. for 0.5 to 4 hours. This heat treatment diffuses the Ge to convert the top silicon film into relaxed Si₁₋ₓGeₓ where x may not be constant through the film. This heat treatment also eliminates some or all of the defects in the SOI film. A second relaxation anneal step 78 may be conducted at a temperature in a range of 1050° C. to 1200° C. for a very short time, such as only a few seconds. A low defect density in the relaxed SiGe on SOI wafer is obtained. Step 80 comprises growing a cap silicon layer. In one embodiment of the method, the silicon cap layer 25 may be deposited before the second, relaxation anneal step 78. Because the underlying SiGe is relaxed, the cap silicon layer is laterally tensily strained. Step 82 comprises growing a gate oxide and then depositing a first polysilicon layer, poly1. Step 84 comprises applying photoresist to protect the active areas. Step 86 comprises etching the poly1, oxide, and SiGe, and then stripping the resist. Step 88 comprises growing a low temperature thermal oxide of 5 nm to 10 nm and then depositing a layer of 50 nm to 200 nm CVD oxide. Step 90 comprises conducting a plasma etch of the oxide to remove all the oxide from the surface of the poly1. This forms a sidewall oxide on the active area. Step 92 comprises depositing 100 nm to 200 nm of polysilicon, poly2. The poly1 and poly2 combine to form the gate electrode. Step 94 comprises application of a photoresist, etching of the polysilicon gate electrode, and then stripping the resist. An additional photoresist is used for the source/drain implant. Step 96 comprises depositing a passivation oxide and the metallization layers. The final device is thus obtained.

During these steps, a low thermal budget is necessary to avoid out diffusion of the Ge into the strained Si layer. In addition, it is well known that the reliability of a thin oxide grown on SiGe is not as good as the reliability of an oxide grown on silicon. This process provides a low thermal budget. Moreover, there is no thin gate oxide grown on a SiGe layer, thereby avoiding the disadvantages of the prior art processes and devices.

Thus, a transistor including a relaxed SiGe layer and a strained top silicon layer on a silicon-on-insulator substrate, and a method of fabricating the same, has been disclosed. Although preferred structures and methods of fabricating the device have been disclosed, it should be appreciated that further variations and modifications may be made thereto without departing from the scope of the invention as defined in the appended claims.

I claim:

1. A method of forming a SiGe/SOI structure, comprising the steps of:
providing a silicon-on-insulator substrate including a buried oxide layer;
depositing a silicon germanium layer on said substrate; and
annealing said silicon germanium layer on said substrate at a temperature of at least 1050° C. for a time period of at least one second.

2. The method of claim 1 wherein said step of annealing said silicon germanium layer is conducted at a temperature of at least 1100° C. for a time period in a range of one to ten seconds.

3. The method of claim 1 wherein said step of annealing said silicon germanium layer is conducted at a temperature of at least 1150° C. for a time period in a range of one to ten seconds.

4. The method of claim 1 wherein prior to said step of annealing said silicon germanium layer on said substrate at a temperature of at least 1050° C., said silicon germanium layer is annealed at a temperature in a range of 550° C. to 1050° C. for a time period in a range of 0.5 to 4.0 hours.

5. The method of claim 1 wherein said silicon germanium layer comprises Si₁₋ₓGeₓ, wherein x is in the range of 0.1 to 0.9.

6. The method of claim 1 wherein said silicon germanium layer comprises Si₁₋ₓGeₓ, wherein x is in the range of 0.2 to 0.5.

7. The method of claim 1 further comprising growing a tensily strained silicon layer on said annealed silicon germanium layer.

8. A transistor produced by the method of claim 1 wherein said transistor includes a relaxed silicon germanium layer and a tensily strained silicon layer positioned thereon.

9. A method of forming a SiGe/SOI structure, comprising the steps of:
providing a silicon-on-insulator substrate including a buried oxide layer;
depositing a silicon germanium layer on said substrate;
conducting a first annealing step comprising annealing said silicon germanium layer on said substrate at a temperature in a range of 550° C. to 1050° C. for a time period in a range of 0.5 to 4.0 hours; and
conducting a second annealing step comprising annealing said silicon germanium layer on said substrate at a temperature of at least 1050° C. for a time period in a range of one to ten seconds.

10. The method of claim 9 wherein said silicon germanium layer comprises Si₁₋ₓGeₓ, wherein x is in the range of 0.1 to 0.9.

11. The method of claim 9 further comprising growing a tensily strained silicon layer on said silicon germanium layer.

12. The method of claim 11 wherein said method produces a transistor including said silicon germanium layer and said tensily strained silicon layer positioned thereon, wherein said silicon germanium layer is relaxed.

13. The method of claim 10 wherein after said first annealing step said silicon germanium layer and silicon from said silicon-on-insulator substrate combine to form a silicon germanium layer defined by Si_{1-y}Ge_{y}, wherein y is less than x.

14. The method of claim 9 wherein said second annealing step is conducted by a method chosen from the group consisting of rapid thermal annealing and laser annealing.

15. The method of claim 9 wherein said method produces a transistor including a top silicon layer adapted for use as a NMOS channel.

16. The method of claim 9 wherein said method produces a transistor including a top silicon layer positioned on a silicon germanium layer, wherein said top silicon layer and said silicon germanium layer are each adapted for use as a pMOS channel.

17. The method of claim 9 wherein said silicon germanium layer is deposited to a thickness of at most 40 nm.

18. A transistor produced by the method of claim 9.
